(19) United States
(12) Patent Application Publication
(10) Pub. No.: US 2006/0255389 A1
(43) Pub. Date: Nov. 16, 2006

(54) Semiconductor device with decoupling capacitor and method of fabricating the same

(76) Inventor: Shigenobu Maeda, Bundang-gu (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/392,556

(22) Filed: Mar. 30, 2006

(30) Foreign Application Priority Data
May 13, 2005 (KR) 10-2005-0040272

(51) Int. Cl. H01L 29/94

(52) U.S. Cl. 257/301

(57) ABSTRACT

The semiconductor device includes a semiconductor layer formed on a semiconductor substrate (e.g., SOI or HOT), and an opening exposing the semiconductor substrate through semiconductor layer. A decoupling capacitor is formed in the opening and includes an epitaxial layer formed in the opening on the semiconductor substrate, and a gate structure disposed on the epitaxial layer.

### BACKGROUND OF THE INVENTION

1. Field of the Invention

Embodiments of the invention relate to a semiconductor device. More particularly, embodiments of the invention relate to a semiconductor device with a decoupling capacitor fabricated on a Silicon On Insulator (SOI) wafer and a bonded wafer, and a method of fabricating the same.

This application claims the benefit of Korean Patent Application No. 10-2005-0040272 filed on May 13, 2005, the subject matter of which is hereby incorporated by reference in its entirety.

2. Description of the Related Art

As semiconductor devices are required to meet increasingly stringent power consumption requirements, circuit designers are faced with increasing difficulties in obtaining (or maintaining) high quality signal transmissions. These transmissions may be “on-chip” as well as to/from the packaged semiconductor device. For example, simultaneous switching of input and/or output signals through Input/Output (I/O) pins associated with a semiconductor device often generate transient noise spikes that may significantly degrade signal quality. Stray noise transients are most commonly introduced to a semiconductor device (e.g., coupled to a signal line) through power elements (e.g., power/ground lines, pads, pins, etc.). In one common mode, noise is capacitively coupled from power element to signal elements. Such noise problems have only been exacerbated in recent years by the development of more densely integrated semiconductor devices having higher I/O pin counts and running at increasingly higher clock frequencies.

As a possible remedy to the adverse effects of power element coupled noise, a decoupling capacitor is added to the power elements. The decoupling capacitor serves to remove the Alternating Current (AC) noise components from the Direct Current (DC) power signals being transmitted by the power elements. The use of decoupling capacitors is particularly common in Large Scale Integration (LSI) systems and devices which generally in a great number of circuit elements integrated onto a single chip. Indeed, for many applications and designs the use of decoupling capacitors is considered essential to the proper operation of the constituent semiconductor device.

FIG. 2 is a block diagram showing an exemplary positional relationship for a decoupling capacitor and related circuit blocks. Referring to FIG. 2, a decoupling capacitor 6 is connected between a power supply Vdd and a ground GND, and is placed in parallel between adjacent circuit block 2 (BLOCK A) and circuit block 4 (BLOCK B) which are also respectively connected between power supply Vdd and the ground GND. Accordingly, noise “N”, especially comprising high frequency noise, produced by circuit block 2 is eliminated by decoupling capacitor 6, thereby preventing any harmful influence (e.g., distortion) from the noise upon the signals being transmitted (e.g., via the power supply line transmitting Vdd) in relation to circuit block 4.

However, each decoupling capacitor occupies a very large area on the constituent semiconductor device. Consider, for example, the conventional decoupling capacitor disclosed in U.S. Pat. No. 6,825,545. This decoupling capacitor is disclosed in relation to a microprocessor requiring a decoupling capacitance of about 1 μF, or approximately 2 μF/cm2. Assuming an oxide layer thickness for the decoupling capacitor of 1.25 nm and a capacitance density of 2.76 μF/cm2, the decoupling capacitor occupy approximately 72% (i.e., 2 μF/cm2/ 2.76 μF/cm2=0.72) of the total surface area of the constituent semiconductor device.

Reliability is also a significant issue in relation to decoupling capacitors. For example, where, as is common, a decoupling capacitor has a Metal Oxide Semiconductor (MOS) structure, the reliability of the gate oxide is a major concern, and this is particularly true given the disproportionately large size of the decoupling capacitor relative to gate oxide regions associated with transistors. Concern over the quality of the gate oxide layer in decoupling capacitors is especially pronounced where the decoupling capacitor is used in conjunction with an SOI wafer or a bonded wafer which are characterized by heightened demand for wafer crystal quality.

FIG. 1 is a sectional view of a conventional semiconductor device comprising a decoupling capacitor. This example assumes a system LSI formed on an SOI wafer. The SOI wafer is widely used because of its reduced junction capacitance relative to bulk wafers.

Referring to FIG. 1, buried oxide as a buried insulating layer 12 is formed on a SOI substrate 10 composed of single-crystalline silicon. Then, a first semiconductor layer 14 composed of silicon is formed on buried insulating layer 12. Logic circuits, such as high performance logic transistors, may be formed on first semiconductor layer 14 in separate circuit block regions (e.g., first circuit block region “A” and second circuit block region “B”).

A gate 22 related to the decoupling capacitor to-be-formed is formed on a gate insulating layer 20 which in turn is formed on first semiconductor layer 14 such that the decoupling capacitor will be interposing between the respective circuit blocks.

Generally, the SOI wafer is fabricated by a method during which oxygen atoms are ion implanted into the substrate of a bulk wafer. The implanted wafer is then subjected to a thermal treatment to form a buried oxide layer at a predetermined depth within the substrate (e.g., Separation by Implanted Oxygen (SIMOX)). However, the surface of first semiconductor layer 14 remaining on the buried oxide layer is greatly damaged by the ion implanting process. Thus, in order to prepare (e.g., planarize) the surface of semiconductor layer 14 to receive further processing it is subjected to a Chemical Mechanical Polishing (CMP). Therefore, the overall crystalline quality of the surface of semiconductor layer 14 is much lower than that of conventional bulk wafers. Consequently, the quality of gate insulating layer 20 formed on the surface of first semiconductor layer 14 may be corresponding low.

This result is particularly hazardous given the size of gate insulating layer in view of the large size of the constituent decoupling capacitor. If an insulation breakdown occurs in this vulnerably gate insulating layer of the decoupling capacitor, the power supply Vdd and ground GND are directly connected to each other. The resulting standby current may thus increase very abruptly or an insufficient amount of power may be supplied due to the voltage drop associated with the current leakage in the gate insulating layer. For these reasons, the semiconductor device containing the decoupling capacitor will never operate properly. Thus, this type of failure in the decoupling capacitor will significantly degrade yield of the semiconductor device.

### SUMMARY OF THE INVENTION

In view of the foregoing, embodiments of the invention provide a semiconductor device comprising a decoupling capacitor having a more reliable gate insulating layer. Embodiments of the invention also provide a method of fabricating a semiconductor device comprising an improved decoupling capacitor having a more reliable gate insulating layer.

Thus, in one embodiment, the invention provides a semiconductor device incorporating a decoupling capacitor, comprising; a semiconductor substrate, a semiconductor layer formed on the semiconductor substrate, an opening form in the semiconductor layer to expose a portion of the semiconductor substrate, an epitaxial layer formed on the semiconductor substrate in the opening, and a decoupling capacitor formed from the epitaxial layer.

In another embodiment, the invention provides a semiconductor device incorporating a decoupling capacitor, comprising; a semiconductor substrate, a semiconductor layer formed on the semiconductor substrate, a plurality of circuit block regions from on the semiconductor substrate and separated by a decoupling capacitor region, and a decoupling capacitor formed in the decoupling capacitor region. The decoupling capacitor comprises an epitaxial layer grown on the semiconductor substrate, a gate insulating layer formed on the epitaxial layer, and a gate formed on the gate insulating layer.

In yet another embodiment, the invention provides a method of fabricating a semiconductor device incorporating a decoupling capacitor, the method comprising; forming a semiconductor layer on a semiconductor substrate, removing a portion of the semiconductor layer to expose the semiconductor substrate through an opening, forming a device isolating layer sidewall portions of the opening, forming an epitaxial layer on the semiconductor substrate exposed through the opening, forming a gate insulating layer on the epitaxial layer, and forming a gate on the gate insulating layer.

In related aspects, the formation of the semiconductor layer on the semiconductor substrate may comprise forming a Silicon On Insulator (SOI) structure further comprising a buried insulating layer between the semiconductor substrate and the semiconductor layer, or forming a Hybrid Orientation Technology (HOT) structure by bonding a semiconductor layer wafer having one surface crystalline orientation to a semiconductor substrate wafer having a different surface crystalline orientation.

In yet another embodiment, the invention provides a method of fabricating a semiconductor device incorporating a decoupling capacitor, the method comprising; forming a semiconductor layer on a semiconductor substrate, removing a portion of the semiconductor layer to expose the semiconductor substrate through an opening, and thereby form a decoupling capacitor region separating a plurality of circuit block regions, depositing an insulating material on the entire surface of the semiconductor substrate, and etching the insulating material to form a device isolating layer on sidewall portions of the opening, forming an epitaxial layer on the semiconductor substrate in the opening, wherein the epitaxial layer is surrounded by the device isolating layer, forming a gate insulating layer on the epitaxial layer, and forming a gate on the gate insulating layer.

### BRIEF DESCRIPTION OF THE DRAWINGS

The above and other features and advantages of the invention will become more apparent upon consideration of several exemplary embodiments with reference to the attached drawings in which:

FIG. 1 is a sectional view of a conventional semiconductor device with a decoupling capacitor formed on a Silicon On Insulator (SOI) substrate;

FIG. 2 is a block diagram showing a positional relation of a general decoupling capacitor;

FIG. 3 is a sectional view of a semiconductor device with a decoupling capacitor according to a first embodiment of the present invention;

FIGS. 4A through 4E are sectional views showing a process of fabricating the semiconductor device shown in FIG. 3;

FIG. 5 is a sectional view of the semiconductor device with a decoupling capacitor according to a second embodiment of the present invention;

FIG. 6 is a sectional view showing the semiconductor device with a decoupling capacitor according to a third embodiment of the present invention;

FIG. 7 is a sectional view showing the semiconductor device with a decoupling capacitor according to a fourth embodiment of the present invention;

FIG. 8 is a sectional view showing the semiconductor device with a decoupling capacitor according to a fifth embodiment of the present invention;

FIGS. 9A through 9D are sectional views showing a process of fabricating the semiconductor device of FIG. 8; and

FIG. 10 is a sectional view of the semiconductor device with a decoupling capacitor according to a sixth embodiment of the present invention.

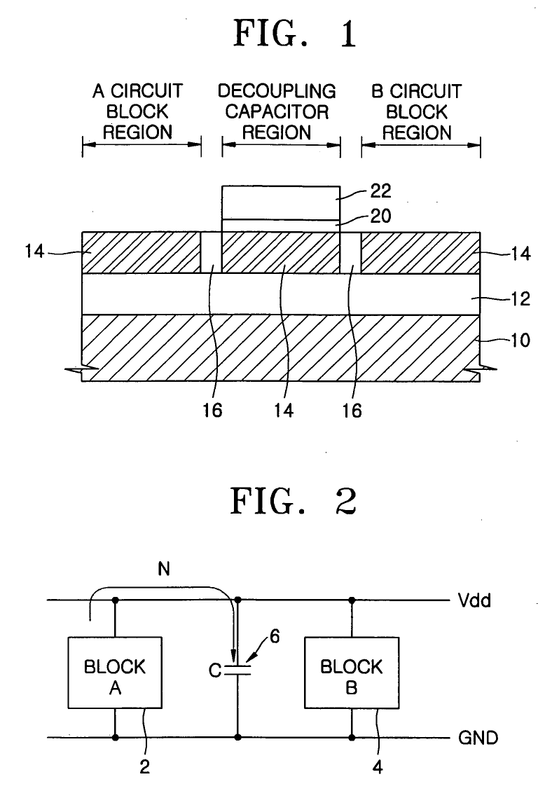

### DESCRIPTION OF EXEMPLARY EMBODIMENTS

The invention will now be described in the context of several exemplary embodiments. The invention may, however, be embodied in many different forms and should not be construed as being limited to only the embodiments set forth herein. Rather, the illustrated embodiments are provided as teaching examples. In the drawings, the thicknesses of layers and regions have been exaggerated for clarity. It will also be understood that when a layer is referred to as being “on” another layer or substrate, it can be directly on the other layer or substrate, or intervening layers may also be present. Like reference numerals in the drawings denote like or similar elements.

In one aspect, the illustrated embodiments describe a gate insulating layer formed on an epitaxial layer having a high quality surface so as to improve the reliability of a gate insulating layer of a decoupling capacitor. As such, embodiments of the invention are particularly well suited for many applications, including those related to system LSI applications implemented on an SOI wafer or a bonded wafer. Such examples are described below, but are merely representative of many other embodiments.

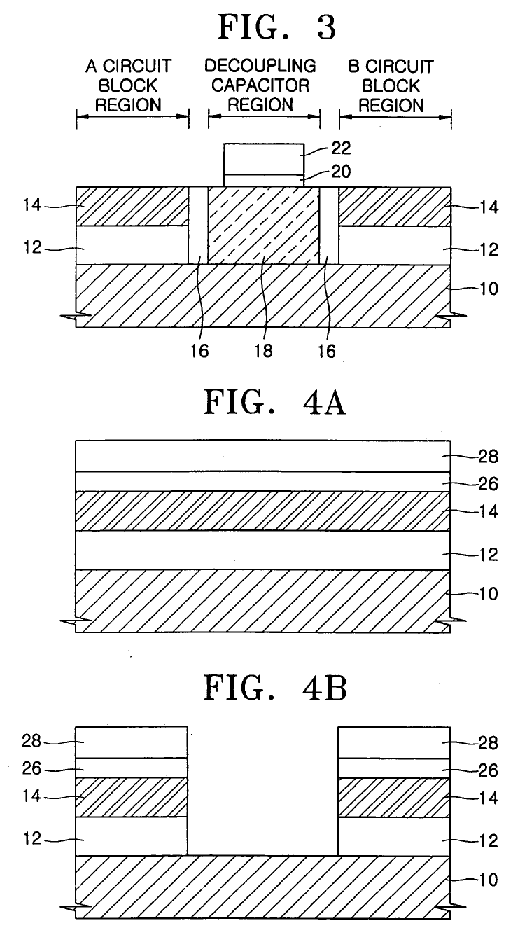

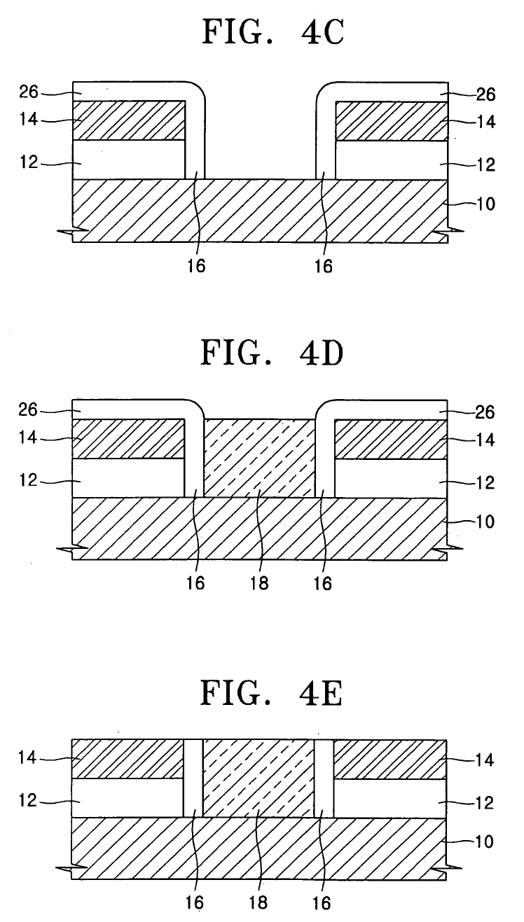

FIG. 3 is a sectional view of a semiconductor device having a decoupling capacitor according to one embodiment of the invention. FIGS. 4A through 4E are related sectional views showing a process adapted to fabricate the semiconductor device of FIG. 3. These examples are drawn to a system LSI formed on a SOI substrate.

Referring to FIG. 3, the decoupling capacitor comprises an epitaxial layer 18, gate insulating layer 20, and a gate 22 sequentially disposed within an opening formed in a specific region of the SOI wafer. In the illustrated example, the SOI wafer comprises a semiconductor layer 14 formed on a buried insulating layer 12. Buried insulating layer 12 is formed on a semiconductor substrate 10. As shown in FIG. 3, the opening in which the decoupling capacitor is formed in created by selective removal of portions of semiconductor 14 and buried insulating layer 12.

Although not shown in the illustrated example, those of ordinary skill in the art will understand that diverse logic circuits (e.g., inverters, NAND or NOR circuit, etc.) may be formed on semiconductor layer 14 within circuit block region “A” and circuit block region “B” adjacent to the decoupling capacitor region.

In the illustrated example, both semiconductor substrate 10 and semiconductor 14 may be formed from single-crystalline silicon. An exemplary method adapted to the formation of either or both of these material layers is described hereafter in some additional detail.

Buried insulating layer 12 may be formed from silicon oxide, or a similar material on semiconductor substrate 10. In one embodiment, buried insulating layer 12 is formed to a thickness of about 30 nm. Following the formation of the opening adapted to receive the decoupling capacitor, a device isolating layer 16 is formed on sidewalls of the opening. Device isolation layer 16 may be formed from silicon oxide. In one embodiment, epitaxial layer 18 is formed from silicon having the same crystalline orientation as semiconductor substrate 10 and is formed on semiconductor substrate 10 of the center of the opening so to be surrounded by device isolating layer 16.

The upper surface of epitaxial layer 18 may be planarized so as to be level with the upper surfaces of adjacent circuit block region “A” and circuit block region “B”. Material layers from which gate insulating layer 20 and gate 22 will be formed are then sequentially deposited surface of semiconductor layer 14 and epitaxial layer 18. These layers are then patterned to form gate 22 of the decoupling capacitor on gate insulating layer 20. Within this exemplary configuration, epitaxial layer 18 forms a lower capacitor plate, gate 22 forms an upper capacitor plate, and gate insulating layer 20 forms a separating dielectric layer between the capacitor plates, thus forming the decoupling capacitor. In one embodiment, gate 22 may be electrically connected to power voltage Vdd as shown in FIG. 2, and epitaxial layer 18 may be connected to a ground through semiconductor substrate 10.

Referring now to FIGS. 4A through 4E, an exemplary method adapted to the fabrication of the semiconductor device shown in FIG. 3 will be described.

Referring to FIG. 4A, an SOI structure is formed by buried insulating layer 12 interposed between semiconductor substrate 10 and semiconductor layer 14 using conventionally understood processes. In one example, however, the SOI structure is formed using a Separation by Implanted Oxygen (SIMOX) method. That is, oxygen species are implanted at a high energy into an upper surface of a silicon substrate. Thus, a region doped with oxygen species is formed at a prescribed depth within the silicon substrate while an undoped layer of silicon is maintained at the surface of the silicon substrate. Then, an annealing process is performed at high temperature to form the SOI structure comprising a buried silicon dioxide (BOX) layer from the region doped with implanted oxygen species separating a lower undoped silicon layer (i.e., semiconductor substrate 10) and a lower undoped silicon layer (i.e., semiconductor layer 14).

Because semiconductor layer 14 and semiconductor substrate 10 originate from the same silicon substrate, the crystalline orientation of these layers is identical (e.g., in the <110> direction). As semiconductor layer 14 maintains a single-crystalline silicon state it is well adapted to serve as an active region in which semiconductor elements may be formed. In one embodiment, semiconductor layer 14 is formed to a thickness of about 100 nm. After the formation of the SOI structure, sacrificial layer 26 formed (e.g.,) from silicon dioxide is formed on semiconductor layer 14 to a thickness of about 100 nm. A photoresist layer 28 is then formed on sacrificial layer 26.

Referring to FIG. 4B, a conventional photolithography process is performed to form a desired pattern of photoresist layer 28 adapted to define the dimensions of the opening in which the decoupling capacitor will be formed. Then, using the patterned photoresist layer as an etch mask, sacrificial layer 26, semiconductor layer 14 and buried insulating layer 12 are subsequently etched to form the opening and selectively expose semiconductor substrate 10. The patterned photoresist layer is then removed by stripping.

Referring to FIG. 4C, a device isolating layer 16 is formed on sidewalls of the opening, but semiconductor substrate 10 remains at least partially exposed through the opening. In one embodiment, after stripping the patterned photoresist layer, an insulating material such as silicon oxide, silicon nitride or silicon oxynitride is deposited on the entire surface of semiconductor substrate 10 including the opening, using a thin film forming technique such as CVD. Then, the insulating material is selectively etched until a portion of semiconductor substrate 10 in the center of the opening is at least partially exposed by the etch-back process. This approach exposes semiconductor substrate 10 while leaving device isolating layer 16 as a sidewall spacer on the inner sidewalls of the opening.

In the illustrated embodiment; device isolating layer 16 is composed of silicon oxide as is sacrificial layer 26. As sacrificial layer 26 and device isolating layer 16 have the same etch selectivity, uniform surface planarization (as described with reference to FIG. 4E) is facilitated. However, the invention is not limited to the use of device isolating layer 16 and sacrificial layer 26. Alternatively, sacrificial layer 26 and device isolating layer 16 may be formed from a common electrically insulating material other than silicon oxide, or be formed from different electrically insulating materials.

In another related aspect, device isolating layer 16 may be formed in contact with residual portions of sacrificial layer 26 proximate to the periphery of the opening, or sacrificial layer 26 may be completely removed before for formation of device isolating layer 16.

Referring to FIG. 4D, epitaxial layer 18 is grown on the portion of semiconductor substrate 10 exposed through the opening using an epitaxy process. Epitaxial layer 18 will grow in a manner defined by the surface conditions of semiconductor substrate 10 (i.e., in relation to crystalline orientation and nature of the single-crystalline silicon material forming semiconductor substrate 10). In one embodiment, epitaxial layer 18 is formed sufficiently thick so as to be level with the upper surface of semiconductor layer 14 (e.g., a thicknesses of about 130 nm in the illustrated example considering exemplary thicknesses for buried-insulating layer 12 and semiconductor layer 14).

Referring to FIG. 4E, the surface of the resulting structure is planarized to remove any portion of sacrificial layer 26 remaining on semiconductor layer 14, and planarize the upper surface of device isolating layer 16 down to the upper surface level of epitaxial layer 18. Such surface planarization may be performed using a conventional CMP process.

Again referring to FIG. 3, gate insulating layer 20 (e.g., silicon oxide) is formed on the entire surface of semiconductor substrate 10 following surface planarization, and a conductive material layer ultimately forming gate 22 is formed on gate insulating layer 20. Then, a photolithography process is performed to define the dimensions of gate insulating layer 20 and gate 22 on epitaxial layer 18, to thereby form the decoupling capacitor. Although not shown in the illustrated example, this combination of photolithography and material layer patterning processes may also be used to simultaneously form predetermined pattern(s) corresponding to a previously-designed logic circuit(s) in circuit block regions “A” and “B”.

FIG. 5 is a sectional view of the semiconductor device incorporating a decoupling capacitor according to anther embodiment of the invention. When compared with the foregoing description, a semiconductor layer 15 has a crystalline orientation different from semiconductor layer 14, and therefore also different from semiconductor substrate 10.

For example, the surface crystalline orientation of semiconductor substrate 10 may be in the <110> direction, but the surface crystalline orientation of semiconductor layer 15 may be in the <100> direction. Such a Hybrid Orientation Technology (HOT) structure is favorable to the formation of an NMOS transistor. Within this configuration and continuing forward with the foregoing assumptions regarding exemplary surface crystalline orientations, the surface crystalline orientation of epitaxial layer 18, as epitaxially grown on semiconductor substrate 10, will be in the <110> direction which is favorable to the formation of a PMOS transistor.

Thus, complementary NMOS and PMOS structures may be selectively formed in different regions of the illustrated example having different surface crystalline orientations. In other words, it is possible to design different device types by considering that electrons have a larger mobility characteristic with respect to a <100> oriented surface crystalline lattice, but holes have a larger mobility characteristic with respect to a <110> oriented surface crystalline lattice.

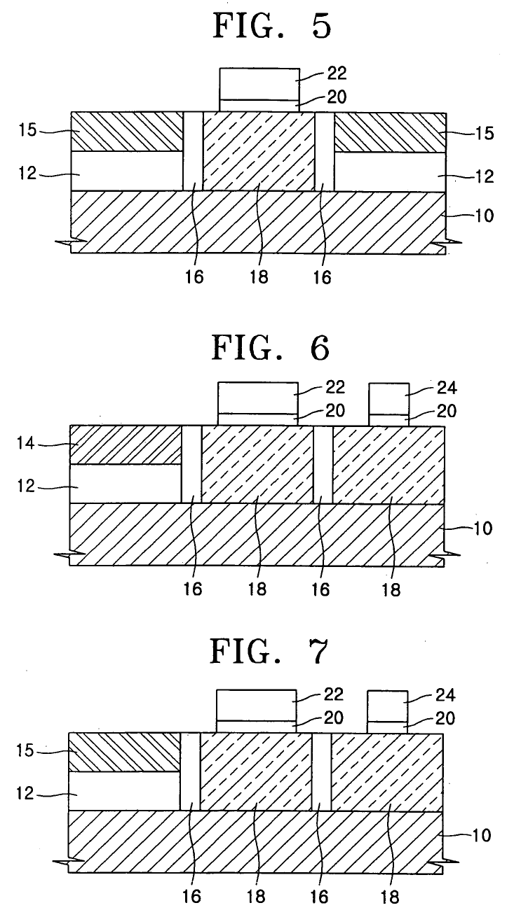

FIG. 6 is a sectional view of a semiconductor device incorporating a decoupling capacitor according to another embodiment of the invention. When compared with foregoing embodiments, epitaxial layer 18 is also formed in circuit block region “B” similar to the decoupling capacitor region.

Referring to FIG. 6, epitaxial layer 18 is formed in the decoupling capacitor region as described above. Then, gate insulating layer 20 and gate 22 are subsequently formed complete the decoupling capacitor. Also as before, buried insulating layer 12 and semiconductor layer 14 are sequentially formed in circuit block region “A”. However, epitaxial layer 18 is also formed on semiconductor substrate 10 in circuit block region “B”. Gate insulating layer 20 is patterned on this region along with the decoupling capacitor region, and a second gate 24 is formed on this portion of gate insulating region 20 to form a semiconductor element (e.g. a transistor) characterized by low leakage current and high reliability.

In the embodiment illustrated in FIG. 6, since the SOI wafer is the same as the one used in the embodiment described with reference to FIG. 3, the surface crystalline orientation of semiconductor layer 14 is identical to that of semiconductor substrate 10. In view of the partial SOI nature of the embodiment illustrated in FIG. 6, semiconductor elements, such as transistors, formed on semiconductor layer 14 within circuit block region “A” will be operated faster than similar devices formed in circuit block region “B”. That is, speed oriented semiconductor elements, such as those commonly used in logic circuits should be formed on semiconductor layer 14 within circuit block region “A”.

In contrast, epitaxial layer 18 formed in circuit block region “B” is well adapted to the formation of semiconductor elements characterized by high reliability and low current leakage. Such semiconductor elements are well suited for use as DRAM cell transistors, for example.

A method adapted to the fabrication of the semiconductor device shown in FIG. 6 will be briefly described with reference to FIGS. 4A through 4E. In the fabrication step shown in FIG. 4B, etching is simultaneously performed to expose the surface of semiconductor substrate 10 in the circuit block region “B” in addition to the decoupling capacitor region. A common epitaxial layer 18 may then be formed on semiconductor layer 10 in both the decoupling capacitor region and circuit block region “B”. Separate epitaxial layers 18 may then be formed by burying a device isolating layer 16 within a separating trench using, for example a Shallow Trench Isolation (STI) process. Alternatively, epitaxial layers 18 may be separately grown on semiconductor substrate 10 in the decoupling capacitor region and circuit block region “B”.

Following the growth of epitaxial layer(s) 18, surface planarization may be performed. Then, an insulating material adapted for use as gate insulating layer 20 as well as a conductive material layer adapted for use as gate 22 and second gate 24 may be subsequently formed and patterned.

FIG. 7 is a sectional view showing the semiconductor device incorporating a decoupling capacitor according to another embodiment of the invention. In this embodiment, semiconductor layer 15 having a different surface crystalline orientation with respect to semiconductor substrate 10 is used instead of the semiconductor layer 14 per the former description. Here again, as with the embodiment described in relation to FIG. 5, semiconductor layer 15 may be well adapted to the formation of a HOT structure favorable to the formation of an NMOS transistor while epitaxial layers 18, as epitaxially grown on semiconductor substrate 10, are favorable to the formation of a PMOS transistor. Therefore, complementary NMOS and PMOS structures may be selectively formed in these respective regions. Again, a semiconductor element formed on semiconductor layer 15 in the SOI structure will generally be operated at a faster speed than a similar device formed on the bulk region. In contrast, a semiconductor device formed on epitaxial layer 18 in the circuit block region “B” will be characterized by low leakage current and high reliability.

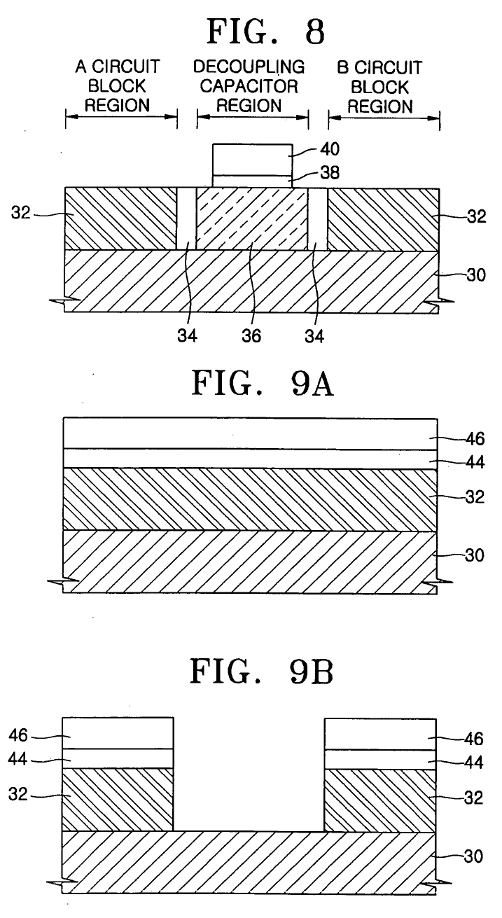

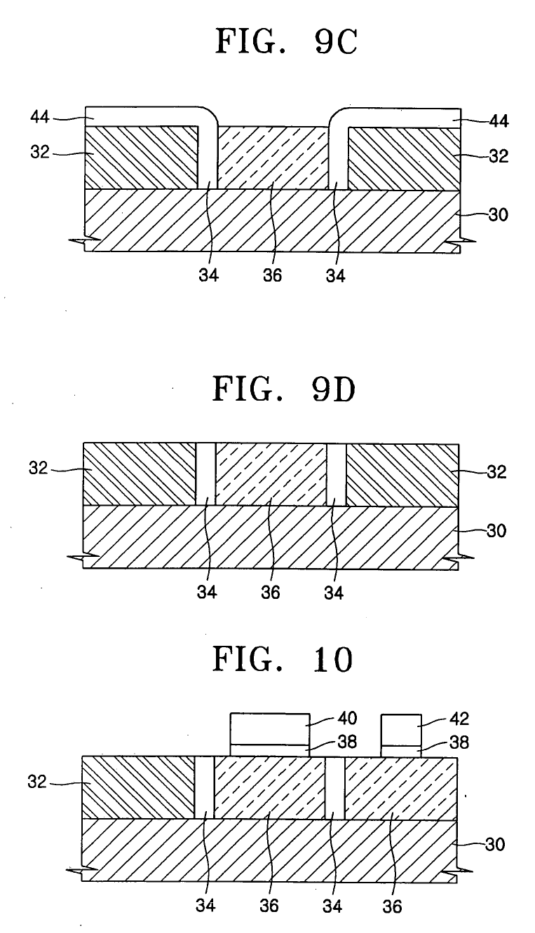

FIG. 8 is a sectional view showing the semiconductor device incorporating a decoupling capacitor according to yet another embodiment of the invention. FIGS. 9A through 9D are related sectional views showing a process adapted to the fabrication of the semiconductor device shown in FIG. 8. This particular example is drawn to a semiconductor device formed on a bonded wafer and comprising a decoupling capacitor and a HOT structure within the context of a system LSI.

Referring to FIG. 8, an opening is formed on a semiconductor layer 32 to receive the decoupling capacitor. The decoupling capacitor comprises an epitaxial layer 36, a gate insulating layer 38, and a gate 40. Although not shown in the illustrated example, various logic circuits (e.g., an inverter, a NAND or a NOR circuit, etc.) may be formed on third semiconductor layer 32 in circuit block region “A” and/or circuit block region “B” adjacent to the decoupling capacitor region.

Semiconductor layer 32 is formed with surface crystalline orientation different from that of semiconductor substrate 30 which is formed from single-crystalline silicon. As above, a defined portion of semiconductor layer 32 is removed to selectively expose semiconductor substrate 30 and form the opening adapted to receive the decoupling capacitor. Device isolating layer 34 formed (e.g.,) from silicon oxide is then formed on sidewall portions of the opening. An epitaxial layer 36 formed (e.g.,) from silicon and having a surface crystalline orientation identical to that of semiconductor substrate 30 is formed on semiconductor substrate 30 in the center of the opening surrounded by device isolating layer 34.

Gate insulating layer 38 and gate 40 are formed to complete the decoupling capacitor. Thus, epitaxial layer 36 forms a lower plate of the decoupling capacitor, and gate 40 forms the upper plate thereof. Gate insulating layer 38 acts as a dielectric film for the decoupling capacitor. As described with reference to FIG. 2, gate 40 may be electrically connected to a power supply Vdd, and epitaxial layer 36 may be connected to a ground GND via the semiconductor substrate 30.

With reference to FIGS. 9A through 9D, a method adapted to the fabrication of the semiconductor device shown in FIG. 8 will be described.

Referring to FIG. 9A, the HOT structure is prepared by bonding semiconductor substrate 30 to second semiconductor layer 32. Semiconductor substrate 30 and second semiconductor layer 32 have different surface crystalline orientations. In one embodiment, the surface crystalline orientation of semiconductor substrate 30 is assumed to be in the <110> direction and the orientation of semiconductor layer 32 is assumed to be in the <100> direction. Then, silicon oxide is formed on semiconductor layer 32 to form sacrificial layer 44. Photoresist layer 46 is then formed on sacrificial layer 44.

Referring to FIG. 9B, a photolithography process is performed to pattern photoresist layer 46 thereby defining the opening adapted to receive the decoupling capacitor. Then, the patterned photoresist is used as an etch mask to etch sacrificial layer 44 and semiconductor layer 32 to selectively expose semiconductor substrate 30. The patterned photoresist layer is then removed by stripping.

Residual portion of sacrificial layer 44 may also be removed at this time, but may remain through the formation of device insulating layer 34. As noted above, this photolithography, patterning and material removal steps may be simultaneously applied to form semiconductor elements on the circuit block regions on semiconductor layer 32.

Referring to FIG. 9C, device isolating layer 34 is formed on sidewall portions of the opening so as to partially expose the surface of semiconductor substrate 30. Then, epitaxial layer 36 is formed in the opening.

In some additional detail, after the patterned photoresist layer (FIG. 9B) is removed by stripping, an insulating material such as silicon oxide, silicon nitride or silicon oxynitride is deposited on the surface of the resulting structure formed on semiconductor substrate 30 including the opening. This deposition may be done using CVD produced thin film of the selected insulating material. This layer of insulating material is then etched to expose semiconductor substrate 30 through the center of the opening. In one embodiment, device isolating layer 34 and sacrificial layer 44 are both formed from silicon oxide.

Thereafter, epitaxial layer 36 is grown on the portion of semiconductor substrate 30 exposed through the opening. Epitaxial layer 36 will grow with the same surface crystalline orientation as (e.g., <110>) as semiconductor substrate 30. Epitaxial layer 36 should be formed sufficiently thick to reach the upper surface of semiconductor layer 32.

Referring to FIG. 9D, any portion of sacrificial layer 44 remaining on semiconductor layer 32 is removed using a surface planarization process, such as CMP.

Subsequently, again referring to FIG. 8, a silicon oxide layer is formed on the entire surface of semiconductor substrate 30 after surface planarization, and a conductive material layer thereon. These layers are then patterned to form gate 40 on gate insulating layer 38.

FIG. 10 is a sectional view of a semiconductor device incorporating a decoupling capacitor according to another embodiment of present invention. As compared with the embodiment described with respect to FIG. 8, epitaxial layer 36 is also formed in circuit block region “B”.

The example shown in FIG. 10 is again drawn to a semiconductor device having HOT structure formed from a bonded wafer. Of note, the surface crystalline orientation of semiconductor substrate 30 (e.g., <110>) has excellent mobility characteristics relative to holes, while the surface crystalline orientation of semiconductor layer 32 (e.g., <100>) has excellent mobility characteristics relative to electrons. Therefore, under the foregoing exemplary assumptions, the surface crystalline orientation of the decoupling capacitor region epitaxially grown on semiconductor substrate 30 and that of epitaxial layer 36 formed in circuit block region “B” will be in the <110> direction which is favorable to the formation of PMOS transistors while the surface crystalline orientation of semiconductor region 32 is favorable to the formation of NMOS transistors. Consequently, complementary NMOS and PMOS structures may be selectively formed in the respective regions.

According to the present invention, a gate insulating layer may be formed on an epitaxial layer without being damaged by ion implanting or etching (e.g., CMP processing) so as to prevent insulation breakdown or leakage of the gate insulating layer of a decoupling capacitor, thereby securing a reliable gate insulating layer. Therefore, reliability of a decoupling capacitor is significantly improved, and yield of the constituent semiconductor device is enhanced.

Furthermore, not only a decoupling capacitor, but also other semiconductor elements may be formed with a low current leakage and high reliability on epitaxial layer(s) in the foregoing exemplary methods.

While the present invention has been particularly shown and described with reference to several exemplary embodiments, it will be understood by those of ordinary skill in the art that various changes in form and detail may be made to these embodiments without departing from the scope of the invention as defined by the following claims.

What is claimed is:

1. A semiconductor device incorporating a decoupling capacitor, comprising:
a semiconductor substrate;
a semiconductor layer formed on the semiconductor substrate;
an opening form in the semiconductor layer to expose a portion of the semiconductor substrate;
an epitaxial layer formed on the semiconductor substrate in the opening; and
a decoupling capacitor formed from the epitaxial layer.

2. The semiconductor device of claim 1, wherein the semiconductor substrate is a single-crystalline silicon substrate, and the epitaxial layer is an epitaxially grown silicon layer having the same surface crystalline orientation as the semiconductor substrate.

3. The semiconductor device of claim 1, further comprising:
a buried insulating layer disposed between the semiconductor substrate and the semiconductor layer.

4. The semiconductor device of claim 1, wherein the semiconductor layer and the epitaxial layer are separated by a device isolating layer.

5. The semiconductor device of claim 1, wherein the semiconductor layer and the epitaxial layer have the same surface crystalline orientation.

6. The semiconductor device of claim 1, wherein the semiconductor layer and the epitaxial layer have different surface crystalline orientations.

7. The semiconductor device of claim 1, further comprising:
a gate insulating layer formed on the epitaxial layer; and,
a gate formed on the gate insulating layer.

8. A semiconductor device incorporating a decoupling capacitor, comprising:
a semiconductor substrate;
a semiconductor layer formed on the semiconductor substrate;
a plurality of circuit block regions from on the semiconductor substrate and separated by a decoupling capacitor region; and
a decoupling capacitor formed in the decoupling capacitor region and comprising;
an epitaxial layer grown on the semiconductor substrate,
a gate insulating layer formed on the epitaxial layer, and
a gate formed on the gate insulating layer.

9. The semiconductor device of claim 8, wherein the semiconductor substrate is a single-crystalline silicon substrate, and the epitaxial layer has the same surface crystalline orientation as the semiconductor substrate.

10. The semiconductor device of claim 8, further comprising:
a buried insulating layer disposed between the semiconductor substrate and the semiconductor layers in the plurality of the circuit block regions.

11. The semiconductor device of claim 8, wherein the plurality of circuit block regions are separated from the epitaxial layer by a device isolating layer.

12. The semiconductor device of claim 8, wherein at least one of the plurality of he circuit block regions comprises an epitaxial semiconductor layer grown on the semiconductor substrate.

13. The semiconductor device of claim 12, wherein one of the plurality of circuit block regions comprises a semiconductor layer adapted to the formation of high speed semiconductor elements, and another one of the plurality of circuit block regions comprises an epitaxial semiconductor layer adapted to the formation of semiconductor elements characterized by low leakage current and high reliability.

14. The semiconductor device of claim 8, wherein the semiconductor layer and the epitaxial layer have the same surface crystalline orientation.

15. The semiconductor device of claim 8, wherein the semiconductor layer and the epitaxial layer have different surface crystalline orientations.

16. The semiconductor device of claim 8, wherein the plurality of circuit block regions and the decoupling capacitor are respectively connected in parallel between a power supply voltage and ground.

17. A method of fabricating a semiconductor device incorporating a decoupling capacitor, the method comprising:
forming a semiconductor layer on a semiconductor substrate;
removing a portion of the semiconductor layer to expose the semiconductor substrate through an opening;
forming a device isolating layer sidewall portions of the opening;
forming an epitaxial layer on the semiconductor substrate exposed through the opening;
forming a gate insulating layer on the epitaxial layer; and
forming a gate on the gate insulating layer.

18. The method of claim 17, wherein forming the semiconductor layer on the semiconductor substrate comprises:
forming a Silicon On Insulator (SOI) structure further comprising a buried insulating layer between the semiconductor substrate and the semiconductor layer.

19. The method of claim 17, wherein forming the semiconductor layer on the semiconductor substrate comprises:
forming a Hybrid Orientation Technology (HOT) structure by bonding a semiconductor layer wafer having one surface crystalline orientation to a semiconductor substrate wafer having a different surface crystalline orientation.

20. The method of claim 17, further comprising:
before forming the gate insulating layer, performing a planarization process to expose the semiconductor layer.

21. The method of claim 17, wherein the forming the device isolating layer on sidewall portions of the opening comprises:
depositing an insulating material layer on the entire surface of the semiconductor substrate including the opening, and etching back the insulating material to expose the semiconductor substrate in the center of the opening.

22. A method of fabricating a semiconductor device incorporating a decoupling capacitor, the method comprising:
forming a semiconductor layer on a semiconductor substrate;
removing a portion of the semiconductor layer to expose the semiconductor substrate through an opening, and thereby form a decoupling capacitor region separating a plurality of circuit block regions;
depositing an insulating material on the entire surface of the semiconductor substrate, and etching the insulating material to form a device isolating layer on sidewall portions of the opening;
forming an epitaxial layer on the semiconductor substrate in the opening, wherein the epitaxial layer is surrounded by the device isolating layer;
forming a gate insulating layer on the epitaxial layer; and
forming a gate on the gate insulating layer.

23. The method of claim 22, wherein forming the semiconductor layer on the semiconductor substrate comprises:
forming a Silicon On Insulator (SOI) structure further comprising a buried insulating layer between the semiconductor substrate and the semiconductor layer.

24. The method of claim 22, wherein forming the semiconductor layer on the semiconductor substrate comprises:
forming a Hybrid Orientation Technology (HOT) structure by bonding a semiconductor layer wafer having one surface crystalline orientation to a semiconductor substrate wafer having a different surface crystalline orientation.

25. The method of claim 22, further comprising: before forming the gate insulating layer, surface planarizing to expose a surface of the semiconductor layer.

26. The method of claim 22, wherein the forming the device isolating layer on sidewall portions of the opening comprises:
depositing an insulating material layer on the semiconductor layer including the opening, and etching back the insulating material to expose the semiconductor substrate in the center of the opening.

27. The method of claim 22, wherein at least one of the plurality of circuit block regions comprises an epitaxial semiconductor layer grown on the semiconductor substrate.

28. The method of claim 27, wherein at least one of the plurality of circuit block regions comprise a semiconductor layers adapted to the formation of high speed semiconductor elements, and wherein another one of the plurality of circuit block regions comprises an epitaxial semiconductor layer adapted to the formation of semiconductor elements characterized by low current leakage and high reliability.

29. The semiconductor device of claim 22, wherein the semiconductor layer and the epitaxial layer have the same surface crystalline orientation.

30. The semiconductor device of claim 22, wherein the semiconductor layer and the epitaxial layer have different surface crystalline orientations.

31. The semiconductor device of claim 22, wherein the plurality of circuit block regions and the decoupling capacitor region are respectively connected in parallel between a power supply voltage and ground.
